(19) United States
(12) Patent Application Publication
(10) Pub. No.: US 2023/0225213 A1
(43) Pub. Date: Jul. 13, 2023

(54) METHOD OF MANUFACTURING PIEZOELECTRIC ELEMENT

(71) Applicant: Japan Display Inc., Tokyo (JP)

(72) Inventor: Toshihiko ITOGA, Tokyo (JP)

(73) Assignee: Japan Display Inc., Tokyo (JP)

(21) Appl. No.: 18/152,772

(22) Filed: Jan. 11, 2023

(30) Foreign Application Priority Data
Jan. 11, 2022 (JP) 2022-002503

(51) Int. Cl. H10N 30/079; H10N 30/078; H10N 30/00

(52) U.S. Cl. CPC H10N 30/079; H10N 30/078; H10N 30/10516

(57) ABSTRACT

According to one embodiment, a method of manufacturing a piezoelectric element, includes forming lower electrodes on an insulating substrate, applying a precursor solution on the insulating substrate and the lower electrodes, drying the precursor solution by firing, thus forming a first precursor layer, patterning the first precursor layer into a shape of a plurality of islands located on the lower electrodes, respectively and crystallizing the island-shaped first precursor layer by firing, thus forming first piezoelectric layers.

### CROSS-REFERENCE TO RELATED APPLICATIONS

This application is based upon and claims the benefit of priority from Japanese Patent Application No. 2022-002503, filed Jan. 11, 2022, the entire contents of which are incorporated herein by reference.

### FIELD

Embodiments described herein relate generally to a method of manufacturing a piezoelectric element.

### BACKGROUND

Some of the piezoelectric elements have such a structure that a piezoelectric material which exhibits an electromechanical conversion function, that is, for example, a piezoelectric layer made of crystallized piezoelectric ceramics or the like, is sandwiched between two electrodes. Such a piezoelectric element can be deformed as voltage is applied thereto by the two electrodes and can be used as an actuator, for example.

For forming the piezoelectric layer, such a method is known that crystals are grown on a silicon wafer using sputtering. However, silicon wafers are not suitable for manufacturing devices with a large area, which increases the manufacturing cost when the device area is expanded, making the product expensive. Under these circumstances, it is effective to manufacture wafers using glass substrates in order to expand the area of devices. In other words, the method of forming a piezoelectric layer on a glass substrate can be employed.

The method of forming the piezoelectric layer by sputtering requires a high-temperature process of about 600° C., which causes deformation of the glass substrate. Therefore, as a method to form the piezoelectric layer below the heat resistance temperature of the glass substrate, a sol-gel solution can be applied on the glass substrate, and the crystallization process is performed by firing.

### BRIEF DESCRIPTION OF THE DRAWINGS

FIG. 1 is a plan view schematically showing a display device according to one embodiment.

FIG. 2 is a cross-sectional view of a piezoelectric element shown in FIG. 1.

FIG. 3 is a diagram showing a processing step of forming a lower electrode on an insulating substrate.

FIG. 4 is a diagram showing a processing step of applying a first precursor solution.

FIG. 5 is a diagram showing a processing step of patterning a first precursor layer.

FIG. 6 is a diagram showing a processing step of firing an island-shaped first precursor layer.

FIG. 7 is a diagram showing a processing step of applying a second precursor solution.

FIG. 8 is a diagram showing a processing step of patterning the second precursor layer.

FIG. 9 is a diagram showing a processing step of firing the island-shaped second precursor layer.

FIG. 10 is a diagram showing a piezoelectric layer formed by the above-mentioned manufacturing steps.

FIG. 11 is a diagram showing another configuration example of an electronic device.

FIG. 12 is a diagram showing a detailed configuration of the piezoelectric layer of the embodiment.

### DETAILED DESCRIPTION

In general, according to one embodiment, a method of manufacturing a piezoelectric element, comprises forming lower electrodes on an insulating substrate, applying a precursor solution on the insulating substrate and the lower electrodes, drying the precursor solution by firing, thus forming a first precursor layer, patterning the first precursor layer into a shape of a plurality of islands located on the lower electrodes, respectively and crystallizing the island-shaped first precursor layer by firing, thus forming first piezoelectric layers.

Embodiments will be described hereinafter with reference to the accompanying drawings.

Note that the disclosure is presented for the sake of exemplification, and any modification and variation conceived within the scope and spirit of the invention by a person having ordinary skill in the art are naturally encompassed in the scope of invention of the present application. Furthermore, a width, thickness, shape, and the like of each element are depicted schematically in the figures as compared to actual embodiments for the sake of simpler explanation, and they do not limit the interpretation of the invention of the present application. Furthermore, in the description and Figures of the present application, structural elements having the same or similar functions will be referred to by the same reference numbers and detailed explanations of them that are considered redundant may be omitted.

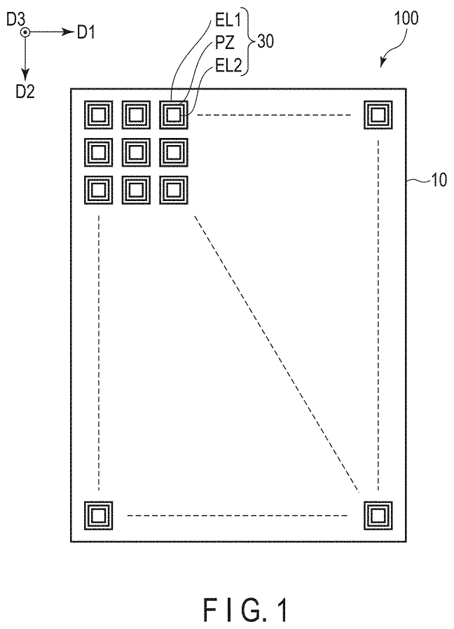

FIG. 1 is a plan view schematically showing an electronic device 100 according to an embodiment.

In this embodiment, a first direction D1, a second direction D2 and a third direction D3 are defined as shown in the drawings. The first direction D1 and the second direction D2 are parallel to a main surface of the electronic device 10 and they intersect each other. The third direction D3 is perpendicular to the first direction D1 and the second direction D2, and is equivalent to the thickness direction of the electronic device 100. The first direction D1 and the second direction D2 intersect perpendicularly in this embodiment, but may intersect at an angle other than right angles. In this specification, the direction toward the tip of the arrow indicating the third direction D3 is referred to as “up” and the direction from the tip of the arrow to the opposite direction is referred to as “down”. It is also assumed that there is an observation position for observing the electronic device 100 on the tip side of the arrow indicating the third direction D3, and viewing from the observation position toward a D1-D2 plane defined by the first direction D1 and the second direction D2 is referred to as plan view.

The electronic device 100 comprises an insulating substrate 10 and a plurality of piezoelectric elements 30. The insulating substrate 10 is formed of glass. The plurality of piezoelectric elements 30 are located on the insulating substrate 10 and are arranged in a matrix along the first direction D1 and the second direction D2.

The piezoelectric elements 30 each comprise a lower electrode EL1, an upper electrode EL2 and a piezoelectric material layer PZ. One piezoelectric layer PZ and one upper electrode EL2 are located on one lower electrode EL1. In other words, the plurality of lower electrodes EL1, the plurality of piezoelectric layers PZ, and the plurality of upper electrodes EL2 are arranged in a matrix, respectively. The piezoelectric element 30 is electrically connected to a piezoelectric element drive circuit, which is not shown in the figure, and performs vibrations, deformation, and other operations based on signals from the piezoelectric element drive circuit. In the example illustrated, the lower electrodes EL1, the upper electrodes EL2 and the piezoelectric layers PZ are rectangular in plan view, but the shapes are not limited to those of this example.

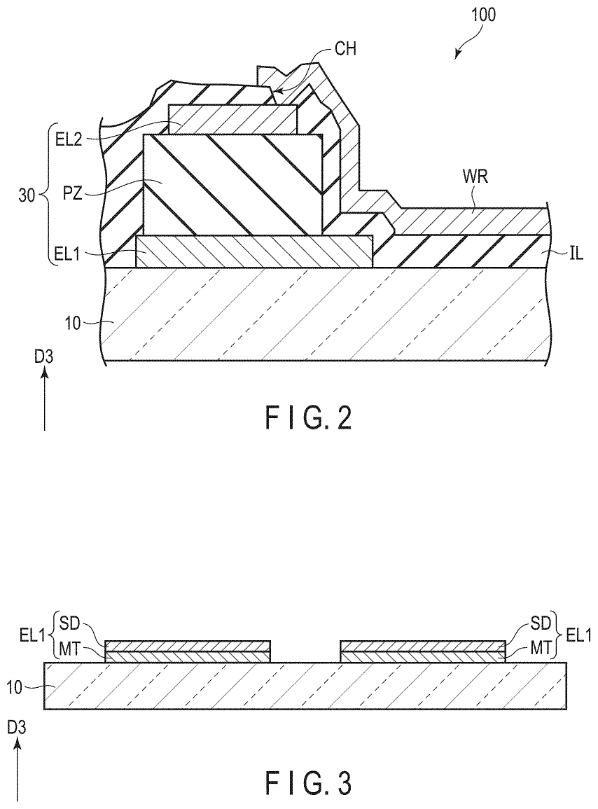

FIG. 2 is a cross-sectional view of the piezoelectric element 30 shown in FIG. 1. The electronic device 100 includes, in addition to those described above, an insulating film IL and a wiring layer WR.

The lower electrode EL1 is located on the insulating substrate 10. The lower electrode EL1 includes, for example, a metal layer MT and a seed layer SD, as will be described later.

The upper electrode EL2 opposes the lower electrode EL1. The upper electrode EL2 is formed of, for example, titanium (Ti), tungsten (W), molybdenum-tungsten (MoW) or the like.

The piezoelectric layer PZ is located between the lower electrode EL1 and the upper electrode EL2. The piezoelectric layer PZ is formed from, for example, lead zirconate titanate (PZT).

The insulating film IL covers the insulating substrate 10 and the piezoelectric element 30. The insulating film IL is made of an inorganic insulating material such as silicon oxide (SiO), silicon nitride (SiN), silicon silicon nitride (SiN) or silicon oxynitride (SiON).

The wiring layer WR is located on the insulating film IL. The wiring layer WR is made of, for example, a metal material such as aluminum (Al), titanium (Ti), molybdenum (Mo), tungsten (W) or the like, or an alloy of any combination of these metal materials, and may be of a single-layer structure or a multilayer structure. The wiring layer WR is connected to the upper electrode EL2 via a contact hole CH formed in the insulating film IL.

Next, with reference to FIGS. 3 to 10, a manufacturing method of forming the piezoelectric element 30 on the insulating substrate 10 will be described.

FIG. 3 is a diagram showing a processing step of forming the lower electrode EL1 on the insulating substrate 10.

In the example illustrated, the lower electrode EL1 comprises a metal layer MT and a seed layer SD. First, the metal layer MT is formed on substantially the entire insulating substrate 10. The seed layer SD is formed on the metal layer MT. The metal layer MT and the seed layer SD are patterned all at once so as to form both into an island shape. The metal layer MT is formed from, for example, platinum (Pt). The seed layer SD is formed from, for example, lanthanum-doped lead titanate (PLT). The seed layer SD is used as a nucleus for crystal growth of the piezoelectric layer PZ.

Note that the step of forming the seed layer SD may be omitted. Further, various components such as a switching element, wiring layer and insulating film are located between the insulating substrate 10 and the lower electrode EL1, though they are omitted from the figure.

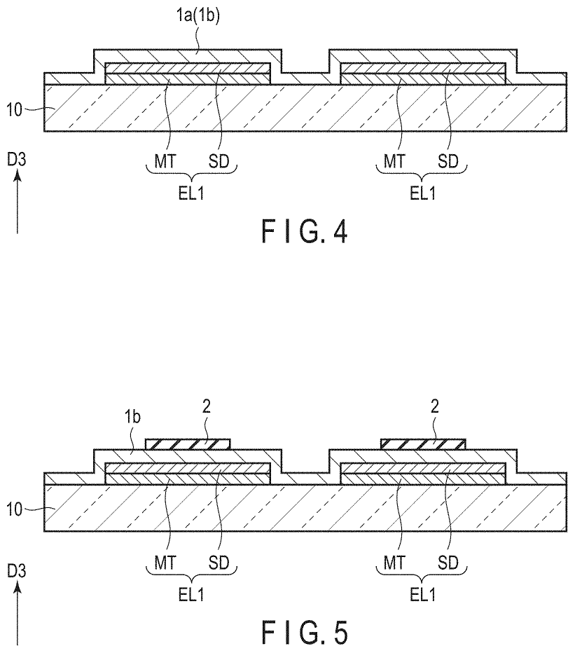

FIG. 4 is a diagram showing a processing step of applying a first precursor solution 1a.

The precursor solution 1a is applied on the insulating substrate 10 and the lower electrode EL1. The precursor solution 1a is applied, for example, by spin-coating, ink-jetting, or spraying method. The precursor solution 1a contains metal elements that constitute the piezoelectric layer PZ.

Then, the precursor solution 1a is dried by firing to form the first precursor layer 1b. The drying of the precursor solution 1a is carried out, for example, at about 200° C. for about 10 minutes. Note that the term “drying” here refers to evaporating the solvent of the precursor solution 1a.

FIG. 5 is a diagram showing a processing step of patterning the first precursor layer 1b.

Next, a resist 2 is patterned on the first precursor layer 1b. The resist 2 is formed at a position overlapping the lower electrode EL1. Then, the first precursor layer 1b is subjected to wet-etching. That is, in the processing step shown in FIG. 5, the first precursor layer 1b is formed into a shape of multiple islands each to be located on the respective lower electrode EL1.

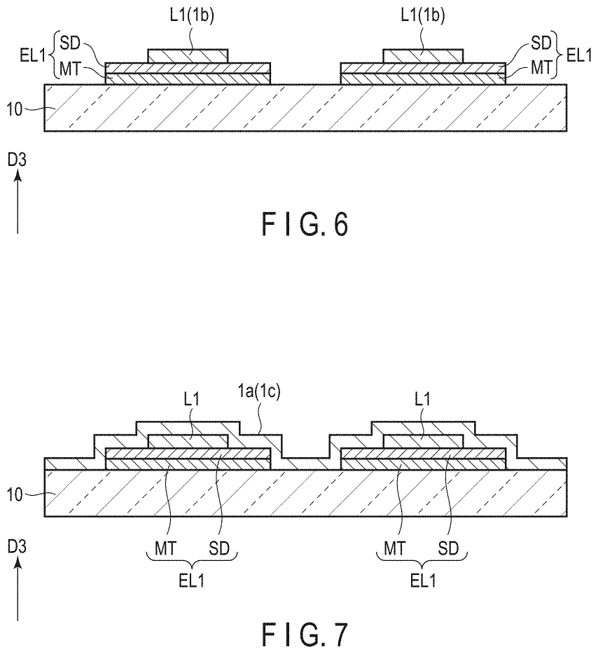

FIG. 6 is a diagram showing a processing step of firing the island-shaped first precursor layer 1b.

Next, the island-shaped first precursor layer 1b is crystallized by firing, thus forming a first piezoelectric layer L1. The firing for crystallizing the first precursor layer 1b is carried out, for example, at about 500° C. for about 30 minutes.

By the above-described process, the first piezoelectric layer L1 is formed. The first piezoelectric layer L1 has a thickness of about 200 nm. The steps shown in FIGS. 4 to 6 are repeated to stack island-shaped piezoelectric layers to form a piezoelectric layer PZ to have a desired film thickness. For example, to form the piezoelectric layer PZ having a film thickness of about 2 μm, the processing steps of FIGS. 4 to 6 are repeated about 10 times.

Note that the firing temperature for drying the precursor solution 1a and the firing temperature for crystallizing the first precursor layer 1b are equal to or lower than the heat resisting temperature of the insulating substrate 10, which is a glass substrate. Therefore, even if the insulating substrate 10 is exposed to the above firing temperatures, deformation of the insulating substrate 10 can be suppressed.

FIG. 7 is a diagram showing a processing step of applying a second precursor solution 1a.

The precursor solution 1a is applied on the insulating substrate 10, the lower electrodes EL1 and the first piezoelectric layer L1. Then the precursor solution 1a is dried by firing, thus forming a second precursor layer 1c.

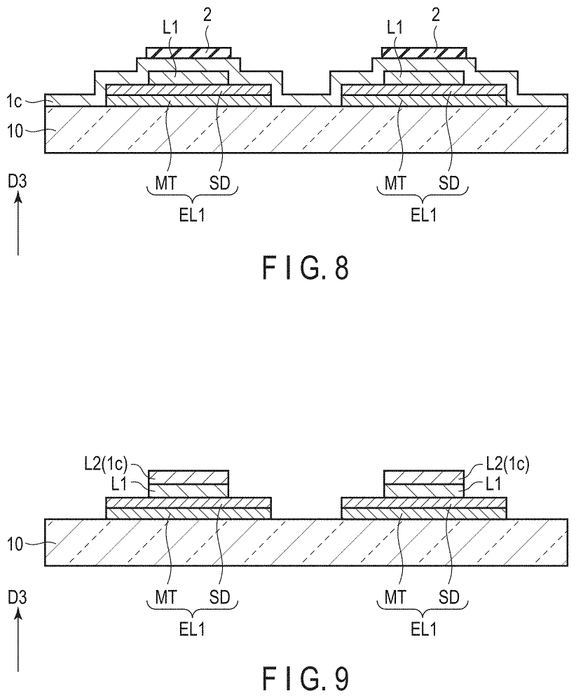

FIG. 8 is a diagram showing a processing step of the second precursor layer 1c.

Next, the resist 2 is patterned on the second precursor layer 1c. The resist 2 is formed at a position overlapping the first piezoelectric layer L1. Then, the second precursor layer 1c is subjected to wet-etching. That is, in the processing step shown in FIG. 8, the second precursor layer 1c is patterned into a shape of multiple islands to be located on the first piezoelectric layer L1. The second precursor layer 1c is patterned into multiple islands to be located on the first piezoelectric layers L1, respectively.

FIG. 9 is a diagram showing a processing step of firing the island-shaped second precursor layer 1c.

Next, the island-shaped second precursor layer 1c is crystallized by firing to form a second piezoelectric layer L2.

By the above-described process, the second piezoelectric layer L2 is formed. The second piezoelectric layer L2 has a thickness of about 200 nm.

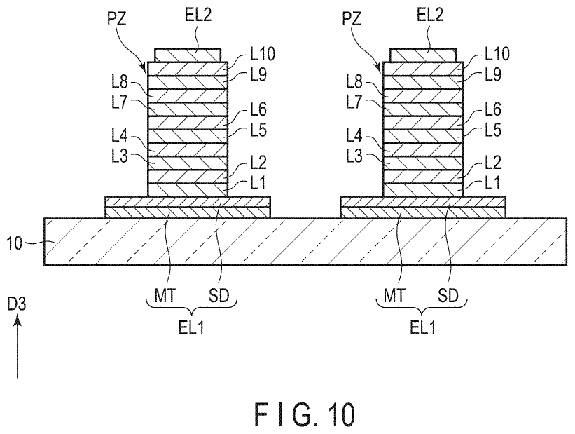

FIG. 10 is a diagram showing piezoelectric layers PZ formed by the manufacturing process described above.

In the example illustrated, each of the piezoelectric layers PZ is constituted by a first piezoelectric layer L1 to a tenth piezoelectric layer L10. The first piezoelectric layer L1 to the tenth piezoelectric layer L10 are stacked along the third direction D3. The number of layers constituting the piezoelectric layer PZ is not limited to that of the example shown in the figure.

After forming the piezoelectric layers PZ, the upper electrode EL2 is patterned on each of the piezoelectric layers PZ. As shown in FIG. 2, an insulating film IL is formed on the upper electrode EL2, and the wiring layer WR is patterned on the insulating film IL, though not illustrated in the figure.

Next, the issues of this embodiment will be described.

In contrast to the configuration described above, the case is assumed where the piezoelectric layers PZ are formed on the entire surface of the insulating substrate 10 without being patterned. When the precursor layer is crystallized by firing to form the piezoelectric layer, as the area of the piezoelectric layer is larger, it is more likely that cracks will occur. Further, as the piezoelectric layer is crystallized over a large area, the stress in the film increases, and the insulating substrate 10 may warp, which may make it impossible to carry out subsequent processes.

According to this method, before firing for crystallization of the precursor layer, the precursor layer is patterned to have a desired size. That is, by carrying out firing for crystallization after reducing the area of the precursor layer, stress is dispersed to individual patterns, thus making it possible to prevent warpage of the insulating substrate 10 and cracks in the piezoelectric layer from occurring. With this embodiment, devices with piezoelectric elements can be fabricated to have large areas. Further, the yield can be improved as well.

Note that in the example illustrated, the lower electrodes EL1 are separated from each other as individual electrodes in each of the piezoelectric element 30, but they may be connected to each other as a common electrode. Similarly, in the example illustrated, the upper electrodes EL2 are separated from each other as individual electrodes in each of the piezoelectric elements 30, but they may be connected to each other as a common electrode.

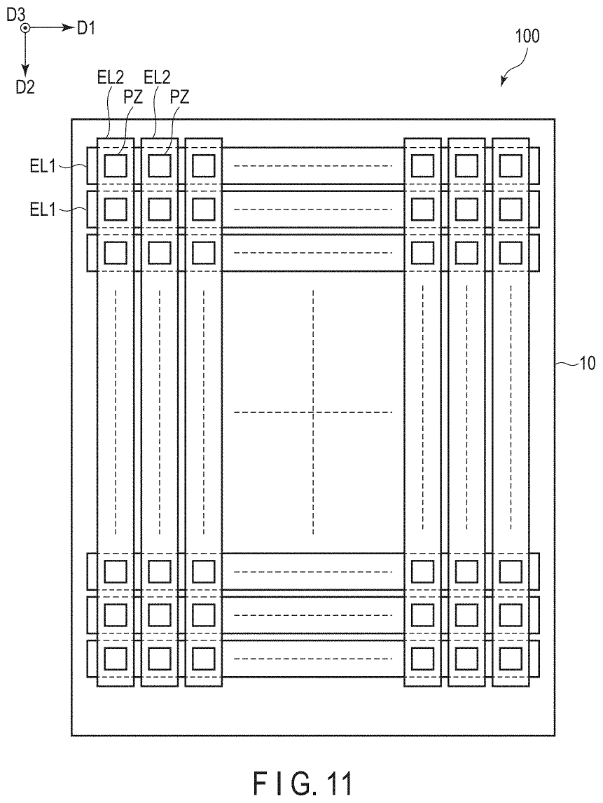

FIG. 11 is a diagram showing another configuration example of the electronic device 100. The configuration shown in FIG. 11 is different from that of FIG. 1 in the shapes of the lower electrodes EL1 and the upper electrodes EL2.

The lower electrodes EL1 extend along the first direction D1 and are aligned along the second direction D2. The upper electrodes EL2 extend along the second direction D2 and are aligned along the first direction D1. The piezoelectric layers PZ are each located at the intersection of the respective lower electrode EL1 and the respective upper electrode EL2. Further, the piezoelectric layers PZ are each located between the respective lower electrode EL1 and the respective upper electrode EL2 along the third direction D3. In the configuration shown in FIG. 11, a plurality of piezoelectric layers PZ are aligned in the first direction D1 on one lower electrode EL1 PZ. Not that the upper electrode EL2 may be formed into an island shape as shown in FIG. 1.

In this configuration example, advantageous effects similar to those described above can be obtained.

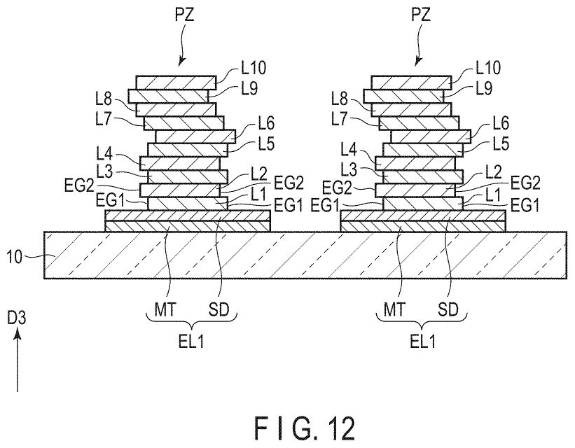

FIG. 12 is a diagram showing a detailed configuration of the piezoelectric layers PZ of this embodiment.

The first piezoelectric layer L1 includes an end portion EG1. The second piezoelectric layer L2 includes an end portion EG2. The end portion EG1 of the first piezoelectric layer L1 does not overlap the end portion EG2 of the second piezoelectric layer L2 along the third direction D3. Similarly, the end portions of the third piezoelectric layer L3 to the tenth piezoelectric layer L10 each do not overlap the respective end portion of the piezoelectric layer located one layer below. The first piezoelectric layer L1 to the tenth piezoelectric layer L10 are formed by patterning each thereof individually, and therefore the end portions are unevenly configured.

As described above, according to this embodiment, it is possible to obtain a method for manufacturing a piezoelectric element, which can improve the yield.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A method of manufacturing a piezoelectric element, comprising:
forming lower electrodes on an insulating substrate;
applying a precursor solution on the insulating substrate and the lower electrodes;
drying the precursor solution by firing, thus forming a first precursor layer;
patterning the first precursor layer into a shape of a plurality of islands located on the lower electrodes, respectively; and
crystallizing the island-shaped first precursor layer by firing, thus forming first piezoelectric layers.

2. The piezoelectric element manufacturing method of claim 1, comprising:
after crystallizing the island-shaped first precursor layers by firing to form the first piezoelectric layers,
applying the precursor solution on the insulating substrate and the first piezoelectric layers;
drying the precursor solution by firing, thus forming a second precursor layer;
patterning the second precursor layer into a shape of a plurality of islands located on the first piezoelectric layer, respectively; and
crystallizing the island-shaped second precursor layer by firing, thus forming second piezoelectric layers.

3. The piezoelectric element manufacturing method of claim 2, wherein
an end portion of each of the first piezoelectric layers does not overlap an end portion of each respective one of the second piezoelectric layers.

4. The piezoelectric element manufacturing method of claim 1, wherein
each of the first piezoelectric layers is located on each of the lower electrodes, and
the lower electrodes and the first piezoelectric layers are arranged in a matrix.

5. The piezoelectric element manufacturing method of claim 1, wherein
the lower electrodes extend along a first direction and are aligned along a second direction intersecting the first direction, and
multiple ones of the first piezoelectric layers are aligned along the first direction on one of the lower electrodes.

6. The piezoelectric element manufacturing method of claim 1, wherein
the insulating substrate is formed of glass.
